(19) United States
(12) Patent Application Publication
(10) Pub. No.: US 2014/0241085 A1
(43) Pub. Date: Aug. 28, 2014

(54) SEMICONDUCTOR MEMORY DEVICE FOR PERFORMING DISABLE OPERATION USING ANTI-FUSE AND METHOD THEREOF

(71) Applicant: Samsung Electronics Co., Ltd., Suwon-Si (KR)

(72) Inventors: Je-Min RYU, Seoul (KR); Sung-Min SEO, Seoul (KR); Yong-Ho CHO, Suwon-si (KR); Nak-Won HEO, Hwaseong-si (KR)

(73) Assignee: SAMSUNG ELECTRONICS CO., LTD., Suwon-Si (KR)

(21) Appl. No.: 14/076,401

(22) Filed: Nov. 11, 2013

(30) Foreign Application Priority Data
Feb. 27, 2013 (KR) 10-2013-0021308

(51) Int. Cl. G11C 29/04

(52) U.S. Cl. CPC G11C 29/04
USPC 365/200

(57) ABSTRACT

A semiconductor memory device for performing a disable operation using an anti-fuse, and method thereof are provided. The semiconductor memory device according to an example embodiment includes a fuse circuit including at least one anti-fuse configured to store fuse data, a memory circuit configured to at least one of read data stored in a memory cell and write data to the memory cell and a fuse controller configured to disable a read/write operation of the memory circuit based on the fuse data.

### CROSS-REFERENCE TO RELATED APPLICATION

This application claims priority under 35 U.S.C. §119 to Korean Patent Application No. 10-2013-0021308 filed on Feb. 27, 2013, the entire contents of which are incorporated herein by reference in their entirety.

### BACKGROUND

1. Field

Embodiments of inventive concepts relate to a semiconductor memory device, and particularly, to a semiconductor memory device for performing a disable operation using an anti-fuse, and/or a method thereof.

2. Description of Related Art

It is possible to disable a defective semiconductor memory device by controlling a laser fuse in the semiconductor memory device at the wafer level.

Further, miniaturization of semiconductor memory devices may exclude the use of a laser fuse.

Moreover, after the semiconductor memory device is installed in a system, a defective semiconductor memory device may be disabled by an external command. However, this may not prevent unnecessary operation of the defective semiconductor memory device.

### SUMMARY

Embodiments of inventive concepts provide a semiconductor memory device for performing a disable operation using an anti-fuse and a method thereof which can easily control an operation of the semiconductor memory device by disabling a defective semiconductor memory device using the anti-fuse.

Embodiments of inventive concepts also provide a semiconductor memory device for performing a disable operation using an anti-fuse and a method thereof which can prevent the semiconductor memory device from being erroneously disabled by erroneously programmed anti-fuse data.

The technical objectives of inventive concepts are not limited to the above disclosure. Other objectives may become apparent to those of ordinary skill in the art based on the following descriptions.

In accordance with inventive concepts, a semiconductor memory device includes a fuse circuit including at least one anti-fuse configured to store fuse data, a memory circuit configured to at least one of read data stored in a memory cell and write data to the memory cell and a fuse controller configured to disable a read/write operation of the memory circuit based on the fuse data.

In one embodiment, the semiconductor memory device may further include a clock control circuit configured to receive an external clock signal and output an internal clock signal to the memory circuit, wherein the fuse controller is configured to disable the clock control circuit based on the fuse data.

In another embodiment, the semiconductor memory device may further include a command control circuit configured to receive an external command signal, and output an internal command signal to the memory circuit, wherein the fuse controller is configured to disable the command control circuit based on the fuse data.

In still another embodiment, the semiconductor memory device may further include an address control circuit configured to receive an external address signal, and output an internal address signal to the memory circuit, wherein the fuse controller is configured to disable the address control circuit.

In yet another embodiment, the semiconductor memory device may further include an input and output circuit configured to buffer data from the memory circuit and output data to the memory circuit, wherein the fuse controller is configured to disable the input and output circuit based on the fuse data.

In yet another embodiment, the fuse controller is configured to enable the read/write operation of the semiconductor memory device based on the fuse data.

In yet another embodiment, the fuse circuit is configured to store mode register set (MRS) data and the fuse controller is configured not to read the MRS data based on the fuse data.

In yet another embodiment, the fuse controller is configured to read the MRS data and perform MRS setting based on the fuse data.

In yet another embodiment, the fuse circuit is configured to store MRS data, the MRS data are included in the fuse data and the fuse controller is configured not to perform MRS setting.

In yet another embodiment, the fuse controller is configured to perform MRS setting based on the fuse data.

In yet another embodiment, the semiconductor memory device is a dynamic random access memory (DRAM) device.

In accordance with another example embodiment of inventive concepts, a method for disabling a read/write operation of a semiconductor memory device including a fuse circuit having at least one anti-fuse configured to store fuse data, and a fuse controller configured to control fuse data, includes reading the fuse data from the fuse circuit and disabling, by the fuse controller, the read/write operation, if there is disable fuse data within the fuse data.

In one embodiment, the disabling of the read/write operation includes disabling a memory control circuit for inputting an external control signal and outputting an internal control signal used in the read/write operation of the memory circuit.

In another embodiment, the method further includes enabling the read/write operation if there is also disable release fuse data within the fuse data.

In still another embodiment, the disabling the read/write operation includes not performing mode register set (MRS) setting, MRS data included in the fuse data.

At least one example embodiment discloses a semiconductor memory device including a fuse controller configured to control a read/write operation of a memory circuit based on fuse data.

In an example embodiment, the semiconductor memory device further includes a fuse circuit including a plurality of anti-fuse cells configured to store the fuse data.

In an example embodiment, the semiconductor memory device further includes a memory control circuit configured to control the memory circuit, wherein the fuse controller is configured to generate a disable signal based on the fuse data and the memory control circuit is configured to one of enable and disable the memory circuit based on the disable signal.

In an example embodiment, the memory control circuit includes a clock control circuit configured to supply a clock signal to the memory circuit, a command control circuit configured to supply a command signal to the memory circuit, and an address control circuit configured to supply an address to the memory circuit, wherein the memory control circuit is configured to disable at least one of the clock control circuit, the command control circuit and the address control circuit based on the disable signal.

In an example embodiment, at least one of the anti-fuse cells includes a fuse, the fuse being one of a capacitor and a transistor, the fuse being coupled to a word read line at a first end of the fuse, and a transistor coupled to the fuse at a second end of the fuse, a gate of the transistor being connected to a word line, another terminal of the transistor being coupled to a bit line.

In an example embodiment, the anti-fuse cells are configured to change from a first resistance state to a second resistance state to store the fuse data.

### BRIEF DESCRIPTION OF THE DRAWINGS

The foregoing and other features and advantages of inventive concepts will be apparent from the more particular description of example embodiments of inventive concepts, as illustrated in the accompanying drawings in which like reference numerals refer to the same parts throughout the different views. The drawings are not necessarily to scale, emphasis instead being placed upon illustrating the principles of inventive concepts. In the drawings:

FIG. 1 is a block diagram illustrating a construction of a semiconductor memory device according to an example embodiment of inventive concepts;

FIG. 2 is a diagram illustrating a fuse circuit according to an example embodiment of inventive concepts;

FIG. 3 is a diagram illustrating a sensing unit according to an example embodiment of inventive concepts;

FIG. 4 is a diagram illustrating a memory control circuit according to an example embodiment of inventive concepts;

FIG. 5 is a flowchart explaining a method of disabling a semiconductor memory device according to one example embodiment of inventive concepts;

FIG. 6 is a flowchart explaining a method of disabling a semiconductor memory device according to another example embodiment of inventive concepts;

FIG. 7 is a block diagram illustrating a construction of a semiconductor memory device according to another example embodiment of inventive concepts;

FIG. 8 is a block diagram illustrating a semiconductor memory package according to one example embodiment of inventive concepts;

FIG. 9 is a diagram illustrating a memory system including the semiconductor memory device of FIG. 1 according to one example embodiment of inventive concepts;

FIG. 10 is a diagram illustrating a memory system including the semiconductor memory device of FIG. 1 according to another example embodiment of inventive concepts;

FIG. 11 is a diagram illustrating a memory module including the semiconductor memory device of FIG. 1 according to one example embodiment of inventive concepts;

FIG. 12 is a diagram illustrating a memory module including the semiconductor memory device of FIG. 1 according to another example embodiment of inventive concepts;

FIG. 13 is a diagram illustrating a memory module including the semiconductor memory device of FIG. 1 according to still another example embodiment of inventive concepts;

FIG. 14 is a diagram illustrating a stacked semiconductor memory device in which a plurality of semiconductor layers are stacked according to an example embodiment of inventive concepts;

FIG. 15 is a diagram illustrating a computer system including the semiconductor memory device of FIG. 1 according to one example embodiment of inventive concepts;

FIG. 16 is a diagram illustrating a computer system including the semiconductor memory device of FIG. 1 according to another example embodiment of inventive concepts; and

FIG. 17 is a diagram illustrating a computer system including the semiconductor memory device of FIG. 1 according to still another example embodiment of inventive concepts.

### DETAILED DESCRIPTION OF EMBODIMENTS

Example embodiments are described below in sufficient detail to enable those of ordinary skill in the art to embody and practice example embodiments. It is important to understand that example embodiments may be embodied in many alternate forms and should not be construed as limited to example embodiments set forth herein.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

It will be understood that, although the terms first, second, A, B, etc. may be used herein in reference to elements of example embodiments, such elements should not be construed as limited by these terms. For example, a first element could be termed a second element, and a second element could be termed a first element, without departing from the scope of example embodiments. Herein, the term “and/or” includes any and all combinations of one or more referents.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein to describe embodiments is not intended to limit the scope of example embodiments. The articles “a,” “an,” and “the” are singular in that they have a single referent, however the use of the singular form in the present document should not preclude the presence of more than one referent. In other words, elements of example embodiments referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein are to be interpreted as is customary in the art to which example embodiments belong. It will be further understood that terms in common usage should also be interpreted as is customary in the relevant art and not in an idealized or overly formal sense unless expressly so defined herein.

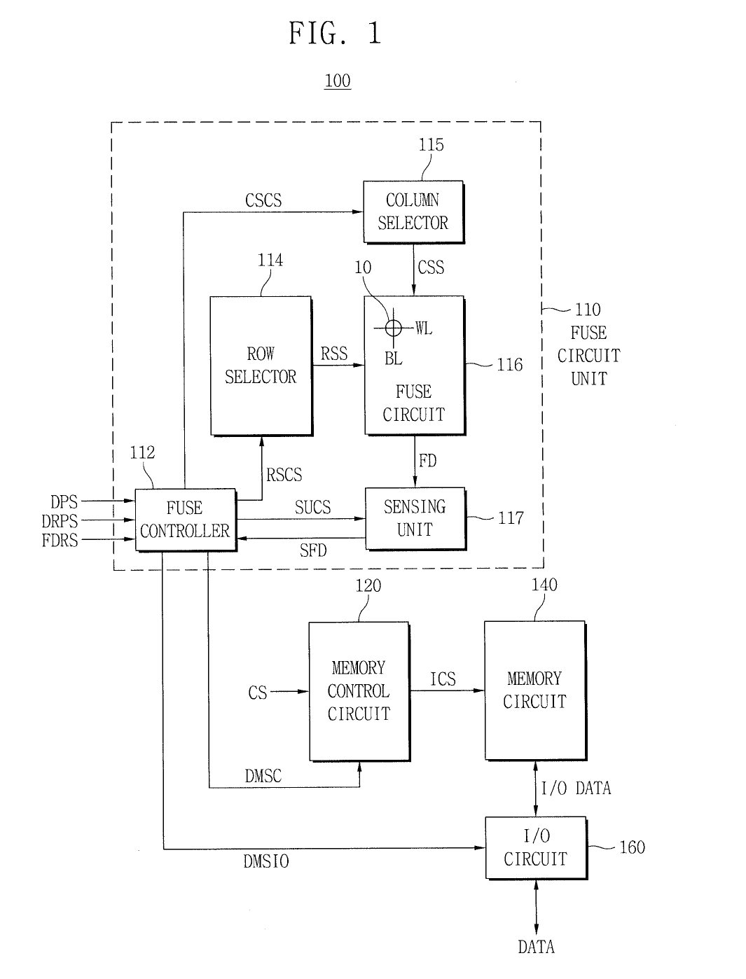

FIG. 1 is a block diagram illustrating a construction of a semiconductor memory device according to one example embodiment of inventive concepts.

Referring to FIG. 1, the semiconductor memory device 100 may include a fuse circuit unit 110, a memory control circuit 120, a memory circuit 140, and an input and output circuit 160. The fuse circuit unit 110 may include a fuse controller 112, a row selector 114, a column selector 115, a fuse circuit 116, and a sensing unit 117.

The fuse circuit unit 110 may read disable fuse data programmed in a disable anti-fuse and disable release fuse data programmed in a disable release anti-fuse, and output a first disable master signal DMSC for the memory control circuit 120 and a second disable master signal DMSIO for the input and output circuit 160 to the memory control circuit 120 and the input and output circuit 160, respectively, based on the disable fuse data and the disable release fuse data.

The fuse controller 112, in order to program the disable fuse data in a fuse cell which is at a first specific location of the fuse circuit 116 in response to a disable program signal DPS input from an exterior, may output a row selector control signal RSCS to the row selector 114 and a column selector control signal CSCS to the column selector 115.

The fuse controller 112, in order to program the disable release fuse data in a fuse cell which is at a second specific location of the fuse circuit 116 in response to a disable release program signal DRPS received from the exterior, may output the row selector control signal RSCS to the row selector 114 and the column selector control signal CSCS to the column selector 115.

The fuse controller 112, in order to read fuse data stored in a fuse cell which is in the fuse circuit 116 in response to a fuse data read signal FDRS received from the exterior, may control the row selector 114, the column selector 115, and the sensing unit 117.

Specifically, the fuse controller 112, in order to read the disable fuse data, the disable release fuse data, and mode register set (MRS) fuse data, may output the row selector control signal RSCS to the row selector 114, the column selector control signal CSCS to the column selector 115, and a sensing unit control signal SUCS to the sensing unit 117.

Additionally, the fuse controller 112 may set a mode register set (MRS) of the semiconductor memory device using the MRS fuse data.

Moreover, the fuse controller 112 may receive sensing fuse data SFD from the sensing unit 117, and if there is disable fuse data and no disable release fuse data within the sensing fuse data SFD, output the disable master signal DMSC for the memory control circuit 120 and the disable master signal DMSIO for the input and output circuit 160 to the memory control circuit 120 and the input and output circuit 160, respectively.

For example, if there is disable fuse data, the fuse controller 112 may output the disable master signals DMSC and DMSIO of a logic “high”, and if there is disable release fuse data, the fuse controller 112 may not output the disable master signals DMSC and DMSIO of the logic “high”.

A row selector 114 may output a row selecting signal RSS for selecting a fuse cell located at a specific row of the fuse circuit 116 in response to the row selector control signal RSCS received from the fuse controller 112. The row selecting signal RSS may be a program voltage, a sensing voltage, and/or a read voltage, applied to the specific row of the fuse circuit 116.

A column selector 115 may output a column selecting signal CSS for selecting a fuse cell located at a specific column of the fuse circuit 116 in response to the column selector control signal CSCS input from the fuse controller 112. The column selecting signal CSS may be a bit line voltage which is applied to the specific column of the fuse circuit 116.

The fuse circuit 116 may include at least one fuse cell 10 which is arranged between at least one row and at least one column.

Fuse data may be stored in the fuse cell 10, and the fuse cell 10 may be an anti-fuse cell.

The sensing unit 117 may sense fuse data FD stored in a specific fuse cell of the fuse circuit 116 in response to the sensing unit control signal SUCS input from the fuse controller 112, and output the sensing fuse data SFD to the fuse controller 112.

The memory control circuit 120 may generate an internal control signal ICS such as an internal command signal, an internal clock signal, an internal address signal, and so on, corresponding to a control signal CS such as a command signal CMD, a clock signal CLK, an address signal ADD, and so on, input from an exterior, and output it to memory circuit 140.

The memory control circuit 120 may disable generation of at least one among the internal command signal, the internal clock signal, the internal address signal, and so on, which are included in the internal control signal ICS in response to the disable master signal DMSC for memory control circuit 120 input from the fuse controller 112.

If the generation of the at least one among the signals included in the internal control signal ICS is disabled, the memory circuit 140 may not perform an operation of writing specific data to a memory cell in response to the internal control signal ICS, or reading the data stored in a specific memory cell.

The memory circuit 140 may include a memory cell array, a column decoder, a row decoder, a sensing circuit, and so on, and in response to the internal control signal ICS, store input data input from an exterior in a specific memory cell of the memory cell array, or output sensing data sensing data stored in the specific memory cell of the memory cell array.

The input and output circuit 160 may buffer output data input from the memory circuit 140 and output it to the exterior, and buffer input data received from the exterior and output it to the memory circuit 140.

The input and output circuit 160 may disable a data buffering operation in response to the disable master signal DMSIO for the input and output circuit 160 input from the fuse controller 112.

If the data buffering operation of the input and output circuit 160 is disabled, the input and output circuit 160 may not be able to receive data to store in the memory cell from the exterior, and output data stored in the memory cell to the exterior.

In an example embodiment of inventive concepts, the semiconductor memory device may be a dynamic random access memory (DRAM) device.

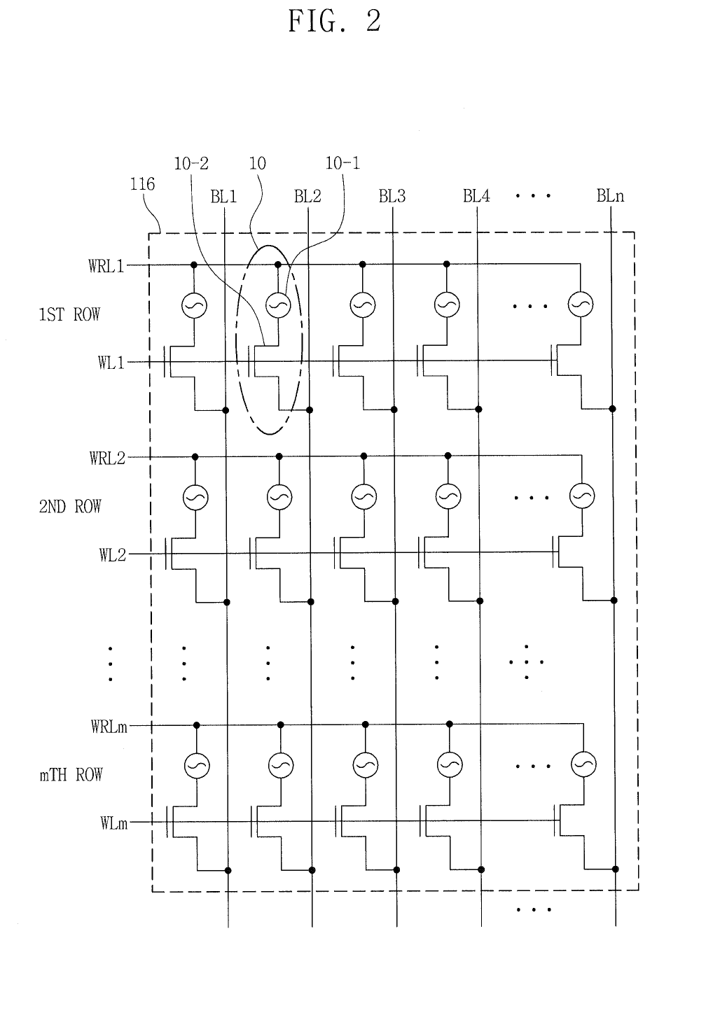

FIG. 2 is a diagram illustrating a fuse circuit according to an example embodiment of inventive concepts.

Referring to FIG. 2, the fuse circuit 116 may include a plurality of fuse cells 10, and information may be stored in each of the plurality of fuse cells 10. Each of the fuse cells 10 may include an anti-fuse, and the anti-fuse may have a characteristic of being changed from a high resistance state to a low resistance state by an electrical signal (i.e., a high voltage signal). Further, the information stored in the anti-fuse cell may be referred to as fuse data.

The fuse circuit 116 may have an array structure in which anti-fuse cells are arranged at locations where a plurality of rows and a plurality of columns intersect. For example, if the fuse circuit 116 has m rows and n columns, the fuse circuit 116 may have m×n anti-fuse cells.

The m word lines WL1˜WLm for accessing the anti-fuse cells 10 arranged in the m rows, and the n bit lines BL1˜BLn arranged corresponding to the n columns for transmitting information read from the anti-fuse cell 10, may be included in the fuse circuit 116.

In an example embodiment of inventive concepts, the fuse circuit 116 may store the disable fuse data for disabling the semiconductor memory device, and the disable release fuse data for releasing a disable state of the semiconductor memory device.

Additionally, the fuse circuit 116 may store mode register set (MRS) fuse data for setting an operation environment of the semiconductor memory device, redundancy fuse data for a defective memory cell, direct current (DC) level trimming fuse data for trimming a DC level of the semiconductor memory device, and so on.

The fuse data may be programmed by applying a programming voltage Vpp to the anti-fuse cell 10 and changing a resistance state of the anti-fuse cell 10. The anti-fuse cell 10 may be changed from a high resistance state to a low resistance state by a programming operation to store information, unlike a general fuse circuit such as a laser fuse circuit, or an electrical fuse circuit, etc. The anti-fuse cell 10 may have a structure including two conductive layers and a dielectric layer therebetween, that is, a capacitor structure, and be programmed by applying a high voltage between the two conductive layers and breaking down the dielectric layer.

In an example embodiment of inventive concepts, the anti-fuse cell 10 may include a fuse 10-1, and a selecting transistor 10-2. Here, the selecting transistor 10-2 may be a metal oxide semiconductor field effect transistor (MOSFET), and the fuse 10-1 may be a fuse capacitor or a MOSFET-type fuse transistor.

If the fuse 10-1 is the fuse capacitor, one end of the fuse capacitor may be a word read line WRL, and the other end of the fuse capacitor may be connected to a source/drain terminal which is one end of the selecting transistor 10-2.

If the fuse 10-1 is the fuse transistor, a gate of the fuse transistor may be connected to a word read line WRL1, a source/drain terminal which is one end of the fuse transistor may be a floating state, and a source/drain which is the other end of the fuse transistor may be connected to the source/drain terminal which is the one end of the selecting transistor 10-2.

A gate of the selecting transistor 10-2 may be connected to a word line WL1, and the source/drain terminal which is the other end of the selecting transistor 10-2 may be connected to a bit line BL2.

A method of programming a fuse cell arranged at a specific row and a specific column may include applying a program voltage Vpp to a word read line of the specific row, adjusting a word line voltage of the specific row and a bit line voltage of the specific column to a condition, breaking down the fuse, and programming the fuse cell.

Information stored in the fuse circuit 116 may be read for each row. For this, one word line may be selected and other word lines may not be selected. If the first row included in the anti-fuse cell 10 of FIG. 2 is selected, a sensing voltage may be applied to a word read line WRL1, and a read voltage may be applied to a word line WL1. Further, during a read operation for the fuse circuit 116, every bit line may be precharged to 0V, and a voltage of 0V may be applied to word read lines and word lines for non-selected rows.

If the anti-fuse cell 10 is programmed, fuse data corresponding to a logic “high” may be output through the sensing unit 117, if the anti-fuse cell 10 is not programmed, the fuse data corresponding to a logic “low” may be output through the sensing unit 117.

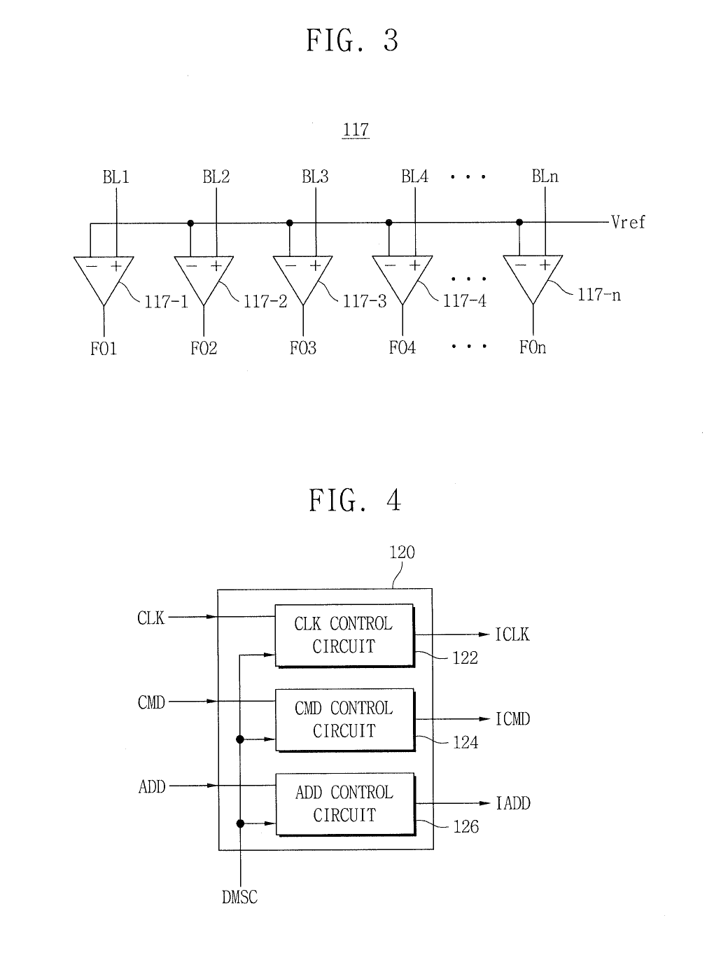

FIG. 3 is a diagram illustrating a sensing unit according to an example embodiment of inventive concepts.

Referring to FIG. 3, the sensing unit 117 may include a sense amplifying circuit corresponding to each of n bit lines BL1˜BLn. Each of the sense amplifying circuits may be composed of sense amplifiers 117-1˜117-n, a positive (+) terminal of the sense amplifier may be connected to a corresponding bit line, and a negative (−) terminal of the sense amplifier may be connected to a reference voltage Vref. Each of the sense amplifiers may output an output signal FO1˜FOn corresponding to fuse data stored in the fuse cell connected to a corresponding bit line.

When a specific fuse cell is selected for reading fuse data, if the specific fuse cell is programmed, a bit line connected to the specific fuse cell by a sensing voltage applied to the fuse cell may be charged, a voltage of a corresponding bit line may be increased and be higher than the reference voltage Vref. Accordingly, the sense amplifier may output an output signal corresponding to a logic “high”, and the output signal may be referred to as sensing fuse data.

Further, if the specific fuse cell is not programmed, the specific fuse cell may become an open-circuit, a sensing voltage applied to the specific fuse cell may have no effect on a corresponding bit line, and a voltage of the corresponding bit line may be maintained at 0V which is lower than the reference voltage Vref. Accordingly, the sense amplifier may output an output signal corresponding to a logic “low”, and the output signal may be referred to as the sensing fuse data.

FIG. 4 is a diagram illustrating a memory control circuit according to an example embodiment of inventive concepts.

Referring to FIG. 4, the memory control circuit 120 may include a clock control circuit 122, a command control circuit 124, and an address control circuit 126.

The clock control circuit 122 may receive an external clock signal CLK, and output a corresponding internal clock signal, and an output operation of outputting the internal clock signal may be disabled in response to the disable master signal DMSC for the memory control circuit 120.

The command control circuit 124 may receive an external command signal CMD including a write command, a read command, etc., and output a corresponding internal command signal. An input operation of inputting the external command signal and an output operation of outputting the internal command signal may be disabled in response to the disable master signal DMSC for the memory control circuit 120.

The address control circuit 126 may receive an external address signal ADD and output an internal address signal IADD corresponding to a column address, a row address, etc., and an output operation of outputting the internal address signal may be disabled in response to the disable master signal DMSC for the memory control circuit 120.

In an example embodiment of inventive concepts, the disable master signal DMSC for the memory control circuit 120 may disable the operations of all of the clock control circuit 122, the command control circuit 124, and the address control circuit 126. In another embodiment, the disable master signal DMSC for the memory control circuit 120 may disable the operation of at least one among the clock control circuit 122, the command control circuit 124, and the address control circuit 126, thereby finally disabling a read/write operation of the memory circuit 140.

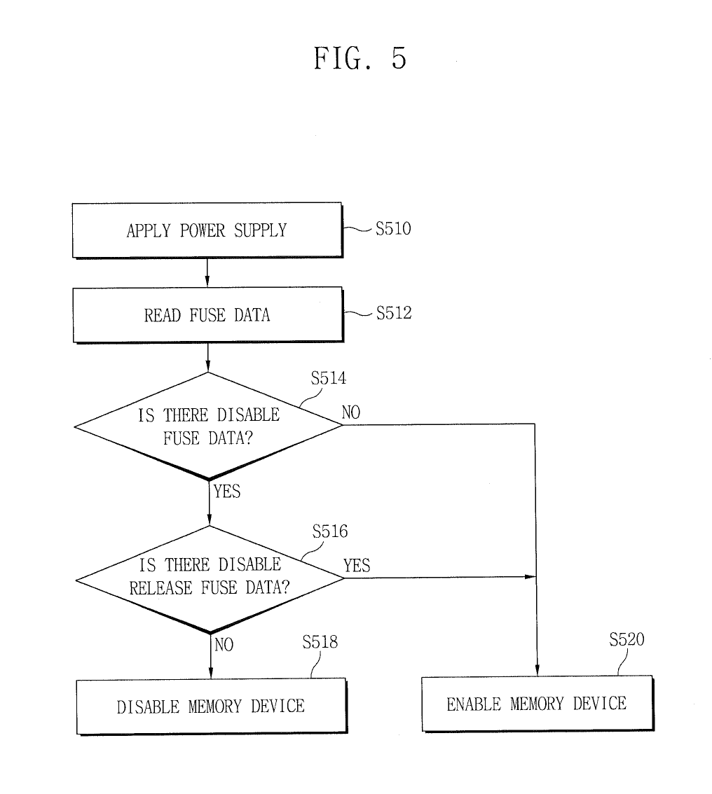

FIG. 5 is a flowchart explaining a method of disabling a semiconductor memory device according to one example embodiment of inventive concepts.

Referring to FIGS. 1 and 5, first, if a power supply is applied to the semiconductor memory device (S510), the fuse controller 112 may receive a fuse data read signal FDRS, control the row selector 114 and the column selector 115, and read fuse data stored in the fuse circuit 116 (S512).

Next, the fuse controller 112 may determine whether there is disable fuse data within the fuse data (S514).

If a result of S514 is that there is disable fuse data, the fuse controller 112 may determine whether there is disable release fuse data within the fuse data (S516).

If a result of S514 is that there is no disable fuse data, or a result of S516 is that there is disable release fuse data, the fuse controller 112 may not output the disable master signal (DMSC and DMSIO of FIG. 1) to the memory control circuit 120 and the input and output circuit 160, thereby finally enabling the semiconductor memory device (S520).

If a result of S516 is that there is no disable release fuse data, the fuse controller 112 may output the disable master signal (DMSC and DMSIO of FIG. 1) to the memory control circuit 120 and the input and output circuit 160, thereby finally disabling data input and output of the semiconductor memory device (S518).

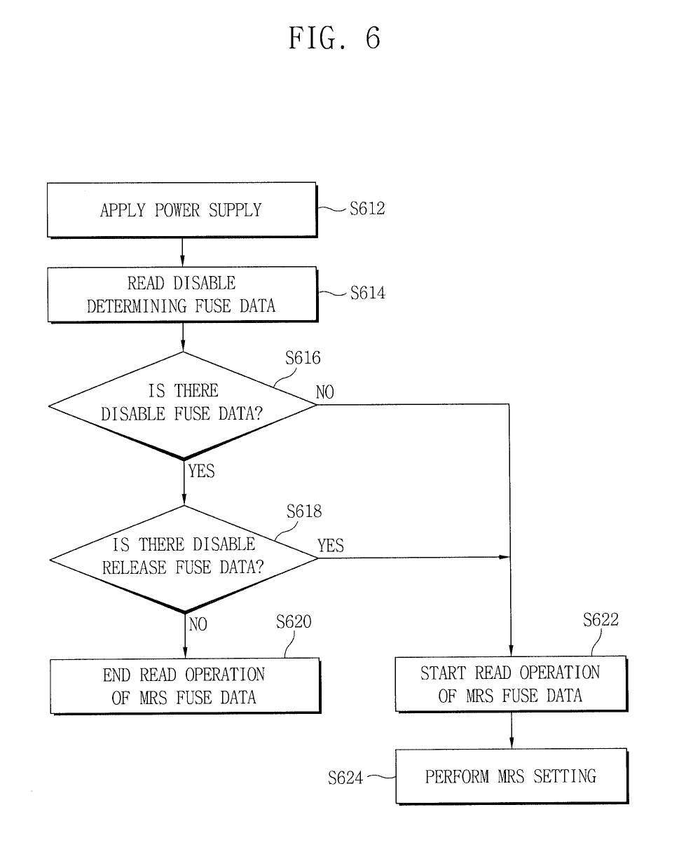

FIG. 6 is a flowchart explaining a method of disabling a semiconductor memory device according to another example embodiment of inventive concepts.

Referring to FIGS. 1 and 6, first, if a power supply is applied to the semiconductor memory device (S612), the fuse controller 112 may receive a fuse data read signal FDRS, control the row selector 114 and the column selector 115, and read disable determining fuse data stored in the fuse circuit 116 (S614).

Next, the fuse controller 112 may determine whether there is disable fuse data within the disable determining fuse data (S616).

If a result of S616 is that there is disable fuse data, the fuse controller 112 may determine whether there is disable release fuse data within the disable determining fuse data (S618).

If a result of S616 is that there is no disable fuse data, or a result of S618 is that there is disable release fuse data, the fuse controller 112 may control the row selector 114 and the column selector 115, and read mode register set (MRS) fuse data stored in the fuse circuit 116 (S622). After that, the fuse controller 112 may perform an MRS setting operation for the semiconductor memory device (S624).

If a result of S618 is that there is no disable release fuse data, the fuse controller 112 may not start but end a read operation of the MRS fuse data stored in the fuse circuit 116 (S620). Finally, the MRS setting operation for the semiconductor memory device may not be performed.

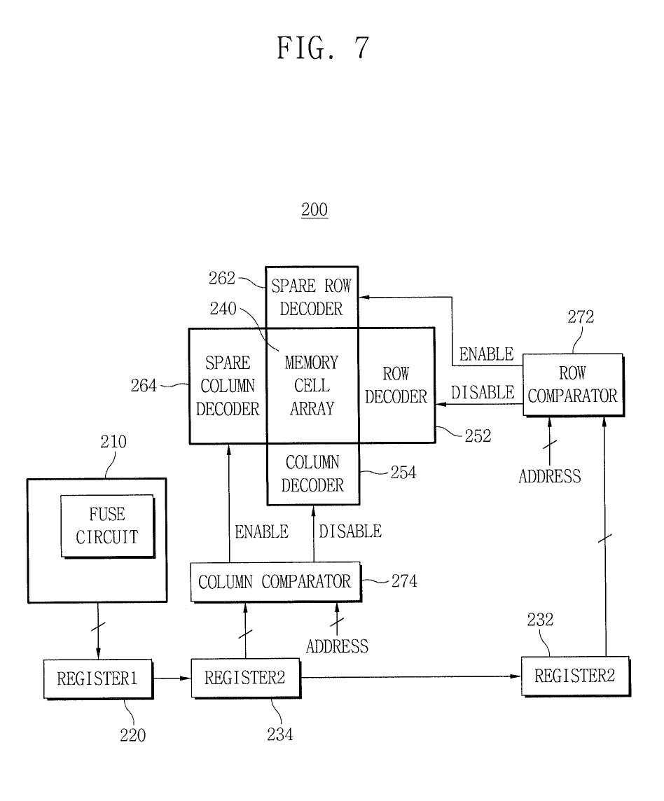

FIG. 7 is a block diagram illustrating a construction of a semiconductor memory device according to another example embodiment of inventive concepts.

Referring to FIG. 7, the semiconductor memory device 200 may include a fuse circuit unit 210, a first register 220, second registers 232 and 234, a memory cell array 240, row and column decoders 252 and 254, spare row and column decoders 262 and 264, and row and column comparators 272 and 274. The first register 220 may store fuse data output from the fuse circuit unit 210, and output the fuse data to a second registers 232 and 234. The second registers 232 and 234 may store the fuse data received from the first register 220. The memory cell array 240 may store data. The row and column decoders 252 and 254 may select and drive at least one among word lines and at least one among bit lines of the memory cell array. The spare row and column decoders 262 and 264 may drive at least one redundant cell. The row and column comparators 272 and 274 may compare address information of a defective cell and address information input from an exterior.

The fuse circuit unit 110 of FIG. 1 may be applicable as the fuse circuit unit 210.

The first register 220 may store fuse data output from the fuse circuit unit 210, and output the fuse data to second registers 232 and 234. Operating conditions of the semiconductor memory device may be set using the fuse data stored in the second registers 232 and 234.

The second registers 232 and 234 may sequentially receive and store each bit of the fuse data output from the first register 220. The second registers 232 and 234 may be arranged adjacent to various circuit blocks requiring the fuse data. For example, the second register 232 for storing row address information of the defective cell may be arranged adjacent to the row comparator 272. Further, the register 234 for storing column address information of the defective cell may be arranged adjacent to the column comparator 274.

The row comparator 272 may compare row address information input from an exterior and row address information of the defective cell, and drive the row decoder 252 or the spare row decoder 262 according to the comparison result. Similarly, the column comparator 274 may compare column address information input from the exterior and column address information of the defective cell, and drive the column decoder 254 or the spare column decoder 264 according to the comparison result.

Each of the row and column comparators 272 and 274 may include a plurality of logic devices for comparing address information from the exterior and address information of the defective cell.

In an example embodiment of inventive concepts, the semiconductor memory device may be a dynamic random access memory (DRAM) device.

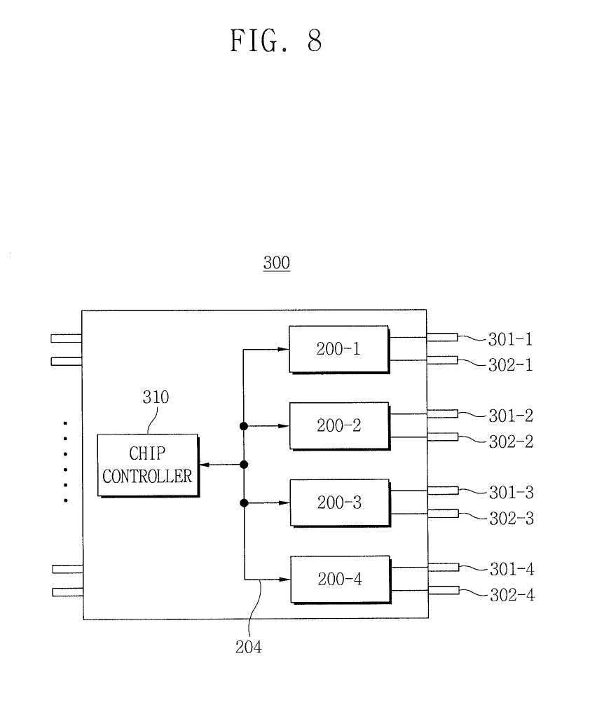

FIG. 8 is a block diagram illustrating a construction of a semiconductor memory package according to one example embodiment of inventive concepts.

Referring to FIG. 8, the semiconductor memory package 300 may include four semiconductor memory devices 200-1 to 200-4, a chip controller 310, and a common line 204. Each of the semiconductor memory devices 200-1 to 200-4 may be a chip type. The chip controller 310 may control the four semiconductor memory devices 200-1 to 200-4. The common line 204 may connect between the chip controller 310 and each of the semiconductor memory devices 200-1 to 200-4. In FIG. 8, there may be no limit to the number of the semiconductor memory devices. That is, the number of the semiconductor memory devices may be larger or smaller than 4.

Each of the semiconductor memory devices 200-1 to 200-4 may include the semiconductor memory device 100 of FIG. 1.

The semiconductor memory package may include a plurality of connection pins, specifically, the semiconductor memory devices 200-1 to 200-4 may be connected to corresponding disable connection pins 301-1 to 301-4 and corresponding disable release connection pins 302-1 to 302-4, respectively.

If the disable program signal is input via the disable connection pins, the disable fuse data may be programmed on a specific anti-fuse of the fuse circuit included in the corresponding semiconductor memory device.

If the disable release program signal is input via the disable release connection pins, the disable release fuse data may be programmed in a specific anti-fuse of the fuse circuit included in the corresponding semiconductor memory device.

If a specific semiconductor memory device is determined to be a defective device, and then programmed as a disabled device, since the specific semiconductor memory device may not receive and output data via the common line 204, it can have no adverse effect on the common line.

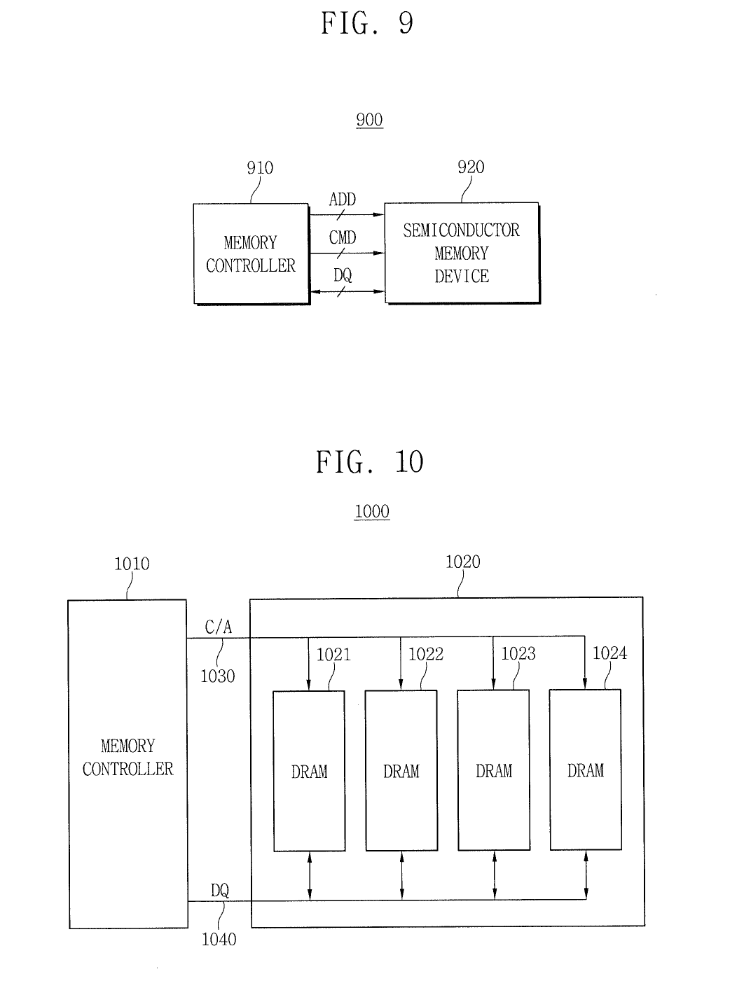

FIG. 9 is a diagram illustrating a memory system including the semiconductor memory device of FIG. 1 according to one example embodiment of inventive concepts.

Referring to FIG. 9, the memory system 900 may include a memory controller 910 and a semiconductor memory device 920.

The memory controller 910 may generate an address signal ADD and a command CMD, and output them to the semiconductor memory device 920 via buses. Data DQ may be transmitted from the memory controller 910 to the semiconductor memory device 920 or from the semiconductor memory device 920 to the memory controller 910 via the buses.

The semiconductor memory device 100 of FIG. 1 may be applicable as the semiconductor memory device 920.

FIG. 10 is a diagram illustrating a memory system including the semiconductor memory device of FIG. 1 according to another example embodiment of inventive concepts.

Referring to FIG. 10, the memory system 1000 may include a memory controller 1010 and a memory module 1020.

The memory module 1020 may include four dynamic random access memory (DRAM) devices. However, the number of the memory module 1020 may be larger than 4. Further, a first to a fourth DRAM devices 1021 to 1024 may be installed on both sides of a substrate of the memory module 1020.

Here, each DRAM device may include the semiconductor memory device 100 of FIG. 1.

The memory controller 1010 may generate a command/address signal C/A and a data signal DQ. The memory module 1020 may operate in response to the command/address signal C/A and the data signal DQ. The command/address signal C/A may be packet data in which the command signal and the address signal are combined in packet type.

The command/address bus 1030 may have a fly-by structure, and electrically connect the first to the fourth DRAM devices 1021 to 1024 with one another. The data signal DQ may be transmitted and received between the memory controller 1010 and the first to the fourth DRAM devices 1021 to 1024 included in the memory module 1020 via the data buses 1040 to 1024.

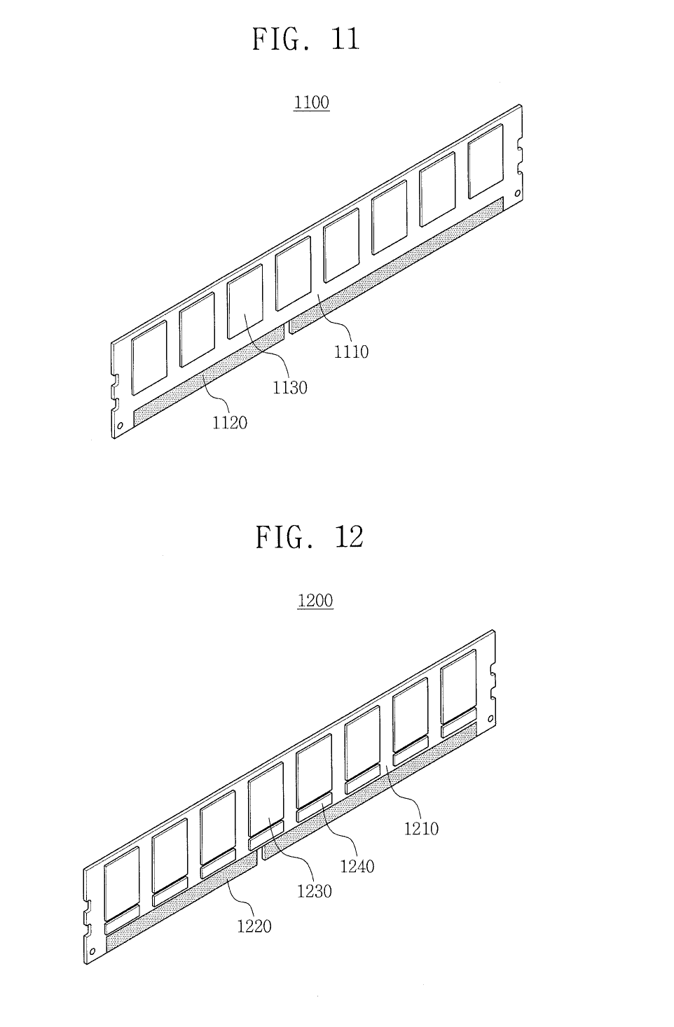

FIG. 11 is a diagram illustrating a memory module including the semiconductor memory device of FIG. 1 according to one example embodiment of inventive concepts.

Referring to FIG. 11, the memory module 1100 may include a plurality of semiconductor memory devices 1130, a printed circuit board 1110, and a connector 1120. The plurality of the semiconductor memory devices 1130 may be installed on an upper surface and a lower surface of the printed circuit board 1110. The connector 1120 may be electrically connected with the plurality of the semiconductor memory devices 1130 via conductive lines. Further, the connector 1120 may be connected to a slot of an external host.

FIG. 12 is a diagram illustrating a memory module including the semiconductor memory device of FIG. 1 according to another example embodiment of inventive concepts.

Referring to FIG. 12, the memory module 1200 may include a plurality of semiconductor memory devices 1230, a printed circuit board 1210, a connector 1220, and a plurality of buffers 1240. Each of the plurality of buffers 1240 may be arranged between each of the semiconductor memory devices and the connector 1220.

The plurality of the buffers 1240 connected to the plurality of the semiconductor memory devices 1230, respectively, may be installed on the upper surface and the lower surface of the printed circuit board 1210. The plurality of the semiconductor memory devices 1230 and the plurality of the buffers 1240 installed on the upper surface and the lower surface of the printed circuit board 1210 may be connected via the plurality of via holes.

FIG. 13 is a diagram illustrating a memory module including the semiconductor memory device of FIG. 1 according to still another example embodiment of inventive concepts.

Referring to FIG. 13, the memory module 1300 may include a plurality of semiconductor memory devices 1330, a printed circuit board 1310, a connector 1320, a plurality of buffers 1340, and a controller 1350.

The plurality of the buffers 1340 connected to the plurality of the semiconductor memory devices 1330, respectively, may be installed on an upper surface and a lower surface of the printed circuit board 1310. The plurality of the semiconductor memory devices 1330 and the plurality of the buffers 1340 installed on the upper surface and the lower surface of the printed circuit board 1310 may be connected via the plurality of via holes. The controller 1350 may transmit a control signal to each of the plurality of the semiconductor memory devices 1330, and transmit and receive data to/from each of the plurality of the semiconductor memory devices 1330.

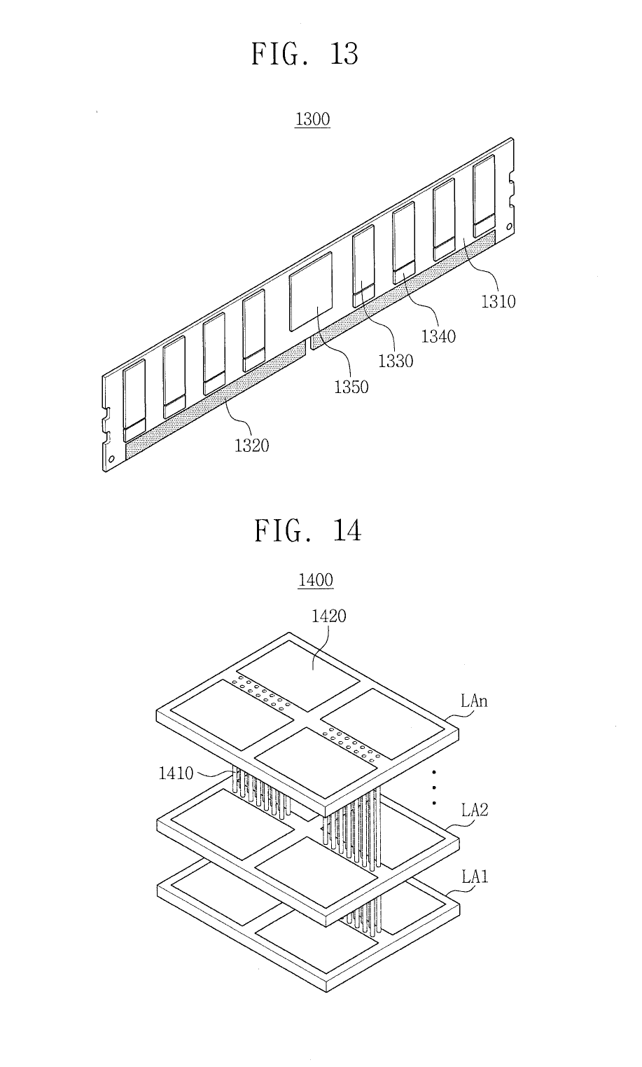

FIG. 14 is a diagram illustrating a stacked semiconductor memory device in which a plurality of semiconductor layers are stacked according to an embodiment of the inventive concept. Each of the semiconductor memory devices included in the memory module of FIG. 11 to FIG. 13 may include the plurality of the semiconductor layers LA1 to LAn.

Referring to FIG. 14, in the stacked semiconductor memory device 1400, the plurality semiconductor layers LA1 to LAn having a stacked structure may be interconnected via through silicon vias (TSVs) 1410.

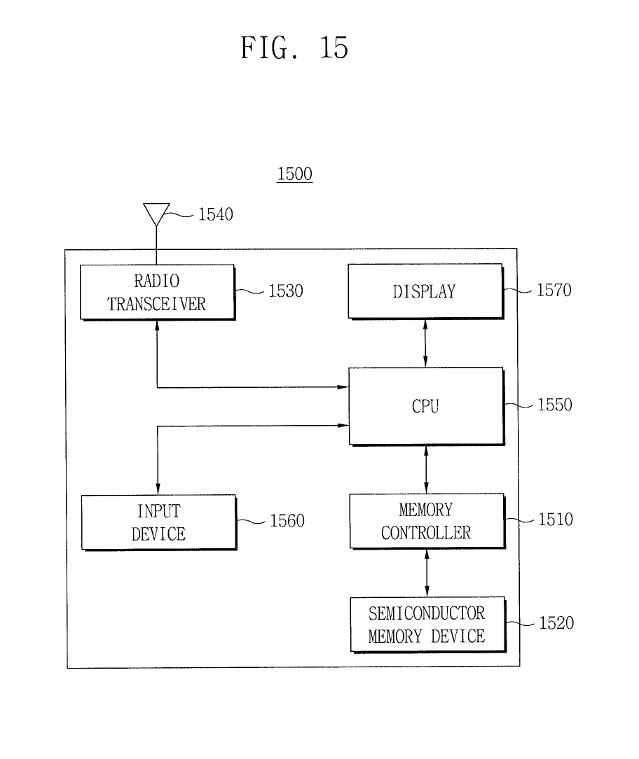

FIG. 15 is a diagram illustrating a computer system including the semiconductor memory device of FIG. 1 according to one example embodiment of inventive concepts.

Referring to FIG. 15, the computer system 1500 may include a semiconductor memory device 1520, a memory controller 1510 for controlling the semiconductor memory device 1520, a wireless transceiver 1530, an antenna 1540, a central processing unit 1550, an input device 1560, and a display unit 1570.

The wireless transceiver 1530 may transmit and receive a wireless signal via the antenna 1540. The wireless transceiver 1530 may convert the wireless signal received via the antenna 1540 into a signal which can be processed in the central processing unit 1550.

Accordingly, the central processing unit 1550 may process a signal output from the wireless transceiver 1530, and transmit the processed signal to the display unit 1570. Further, the wireless transceiver 1530 may convert the signal output from the central processing unit 1550 into the wireless signal, and transmit the converted wireless signal to the external apparatus via the antenna 1540.

The input device 1560 may receive a control signal for controlling an operation of the central processing unit 1550, or data processed by the central processing unit 1550. The input device 1560 may be implemented by a pointing device such as a touch pad, a computer mouse, a keypad, or a keyboard.

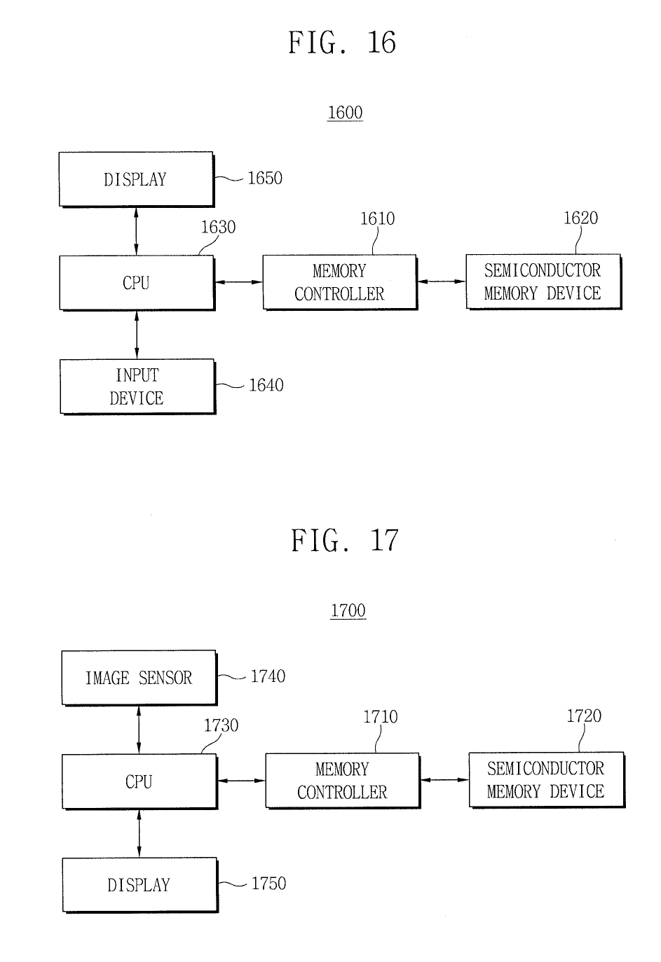

FIG. 16 is a diagram illustrating a computer system including the semiconductor memory device of FIG. 1 according to another example embodiment of inventive concepts.

Referring to FIG. 16, the computer system may be implemented by a personal computer (PC), a network server, a tablet PC, a net-book, an e-reader, a personal digital assistant (PDA), a portable multimedia player (PMP), an MP3 player, or an MP4 player.

The computer system 1600 may include a semiconductor memory device 1620, a memory controller 1610 for controlling a data processing operation of the semiconductor memory device 1620, a central processing unit 1630, an input device 1640, and a display unit 1650.

The central processing unit 1630 may display data stored in the semiconductor memory device 1620 via the display unit 1650 according to data input via the input device 1640. The input device 1640 may be implemented by a pointing device such as a touch pad, a computer mouse, a keypad, or a keyboard. The central processing unit 1630 may control overall operations of the computer system 1600, and control an operation of the memory controller 1610.

According to an embodiment, the memory controller 1610 for controlling an operation of the semiconductor memory device 1620 may be implemented as a portion of the central processing unit 1630. Further, the memory controller 1610 may be implemented as an individual chip which is separated from the central processing unit 1630.

FIG. 17 is a diagram illustrating a computer system including the semiconductor memory device of FIG. 1 according to still another example embodiment of inventive concepts.

Referring to FIG. 17, the computer system 1700 may be implemented by an image processing device, for example, a digital camera or a mobile phone including the digital camera, a smart phone, or a tablet PC.

The computer system 1700 may include a semiconductor memory device 1720, and a memory controller 1710 for controlling a data processing operation, for example, a write operation or a read operation of the semiconductor memory device 1720. Further, the computer system 1700 may further include a central processing unit 1730, an image sensor 1740, and a display unit 1750.

The image sensor 1740 of the computer system 1700 may convert an optical image into a digital signal, and the converted digital signal may be transmitted to the central processing unit 1730 or the memory controller 1710. According to the control of the central processing unit 1730, the converted digital signal may be displayed via the display unit 1750 or stored in the semiconductor memory device 1720 via the memory controller 1710.

Additionally, the data stored in the semiconductor memory device 1720 may be displayed via the display unit 1750 according to the control of the central processing unit 1730 or the memory controller 1710. According to an example embodiment, the memory controller 1710 for controlling an operation of the semiconductor memory device 1720 may be implemented as a portion of the central processing unit 1730. Further, the memory controller 1710 may be implemented as an individual chip which is separated from the central processing unit 1730.

Inventive concepts may be applicable to a semiconductor memory device, and particularly, a semiconductor memory device which can perform a disable operation using an anti-fuse.

The foregoing is illustrative of example embodiments and is not to be construed as limiting thereof. Although a few example embodiments have been described, those skilled in the art will readily appreciate that many modifications are possible without materially departing from the novel teachings and advantages. Accordingly, all such modifications are intended to be included within the scope of inventive concepts as defined in the claims. In the claims, means-plus-function clauses are intended to cover the structures described herein as performing the recited function, and not only structural equivalents but also equivalent structures.

What is claimed is:

1. A semiconductor memory device comprising:
a fuse circuit including at least one anti-fuse configured to store fuse data;
a memory circuit configured to at least one of read data stored in a memory cell and write data to the memory cell; and
a fuse controller configured to disable a read/write operation of the memory circuit based on the fuse data.

2. The device according to claim 1, further comprising:
a clock control circuit configured to receive an external clock signal and output an internal clock signal to the memory circuit,
wherein the fuse controller is configured to disable the clock control circuit based on the fuse data.

3. The device according to claim 1, further comprising:
a command control circuit configured to receive an external command signal and output an internal command signal to the memory circuit,
wherein the fuse controller is configured to disable the command control circuit based on the fuse data.

4. The device according to claim 1, further comprising:
an address control circuit configured to receive an external address signal, and output an internal address signal to the memory circuit,
wherein the fuse controller is configured to disable the address control circuit based on the fuse data.

5. The device according to claim 1, further comprising:
an input and output circuit configured to buffer data from the memory circuit and output other data to the memory circuit,
wherein the fuse controller is configured to disable the input and output circuit based on the fuse data.

6. The device according to claim 1, wherein the fuse controller is configured to enable the read/write operation of the semiconductor memory device based on the fuse data.

7. The device according to claim 1, wherein the fuse circuit is configured to store mode register set (MRS) data and the fuse controller is configured not to read the MRS data based on the fuse data.

8. The device according to claim 7, wherein the fuse controller is configured to read the MRS data and perform MRS setting when the fuse data further has disable release data.

9. The device according to claim 1, wherein the fuse circuit is configured to store MRS data, the MRS data are included in the fuse data and the fuse controller is configured not to perform MRS setting.

10. The device according to claim 9, wherein the fuse controller is configured to perform MRS setting when the fuse data further has disable release data.

11. The device according to claim 1, wherein the semiconductor memory device is a dynamic random access memory (DRAM) device.

12. A method for disabling a read/write operation of a semiconductor memory device including a fuse circuit having at least one anti-fuse configured to store fuse data, the method comprising:
reading the fuse data from the fuse circuit;
disabling, by a fuse controller, the read/write operation, if there is disable fuse data within the fuse data.

13. The method according to claim 12, wherein the disabling of the read/write operation includes disabling a memory control circuit for inputting an external control signal and outputting an internal control signal used in the read/write operation of the memory circuit.

14. The method according to claim 12, further comprising:
enabling the read/write operation, if there is also disable release fuse data within the fuse data.

15. The method according to claim 12, wherein the disabling the read/write operation includes not performing mode register set (MRS) setting, MRS data included in the fuse data.

16. A semiconductor memory device comprising:
a fuse controller configured to control a read/write operation of a memory circuit based on fuse data.

17. The semiconductor memory device of claim 16, further comprising:
a fuse circuit including a plurality of anti-fuse cells configured to store the fuse data.

18. The semiconductor memory device of claim 17, further comprising:
a memory control circuit configured to control the memory circuit, wherein
the fuse controller is configured to generate a disable signal based on the fuse data and the memory control circuit is configured to one of enable and disable the memory circuit based on the disable signal.

19. The semiconductor memory device of claim 18, wherein the memory control circuit includes,
a clock control circuit configured to supply a clock signal to the memory circuit,
a command control circuit configured to supply a command signal to the memory circuit, and
an address control circuit configured to supply an address to the memory circuit, wherein
the memory control circuit is configured to disable at least one of the clock control circuit, the command control circuit and the address control circuit based on the disable signal.

20. The semiconductor memory device of claim 17, wherein at least one of the anti-fuse cells includes,
a fuse, the fuse being one of a capacitor and a transistor, the fuse being coupled to a word read line at a first end of the fuse, and
a transistor coupled to the fuse at a second end of the fuse, a gate of the transistor being connected to a word line, another terminal of the transistor being coupled to a bit line.
